(19) United States
(12) Patent Application Publication
(10) Pub. No.: US 2026/0047359 A1
(43) Pub. Date: Feb. 12, 2026

(54) METHOD FOR MANUFACTURING SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventor: Masaharu Shimabayashi, Ibo Hyogo (JP)

(21) Appl. No.: 19/360,641

(22) Filed: Oct. 16, 2025

Related U.S. Application Data
(63) Continuation of application No. PCT/JP2023/046212, filed on Dec. 22, 2023.

(30) Foreign Application Priority Data
Jul. 24, 2023 (JP) 2023-120158

(51) Int. Cl. H01L 21/02; C23C 16/04; C23C 16/24; C23C 16/40; C23C 16/455; C23C 16/56; H10D 64/01

(52) U.S. Cl. CPC H01L 21/02236; C23C 16/045; C23C 16/24; C23C 16/402; C23C 16/45525; C23C 16/56; H01L 21/02164; H01L 21/0228; H10D 64/025

(57) ABSTRACT

A method for manufacturing a semiconductor device according to an embodiment has a first film formation step, a second film formation step, and an oxidizing step. In the first film formation step, a first coating film made of silicon is formed on a surface of a base material made of silicon carbide. In the second film formation step, a second coating film is formed on a surface of the first coating film. In the oxidizing step, the first coating film is thermally oxidized from a surface side to form a third coating film. In the second film formation step, on a part of the first coating film, the second coating film is not formed, and the part is exposed. Alternatively, in the second film formation step, a film thickness of the second coating film formed on the part of the first coating film is smaller than a film thickness of the second coating film formed on a different part.

### CROSS-REFERENCE TO RELATED APPLICATION

The present application claims priority based on Japanese Patent Application No. 2023-120158 filed on Jul. 24, 2023, the contents of which are incorporated herein by reference.

### FIELD

An embodiment of the present invention relates to a method for manufacturing a semiconductor device.

### BACKGROUND

In recent years, as semiconductor devices have become more microminiaturized, there is a demand for a structure in which withstand voltage is increased while microminiaturization is realized by locally thickening an insulating film at an area where dielectric breakdown is likely to occur inside a semiconductor device. Hence, a method for forming a locally thick insulating film using a film formation technique such as chemical vapor deposition (which will hereinafter be referred to as CVD) has been proposed. However, in this case, there is a problem that impurities are likely to be incorporated into the insulating film.

### BRIEF DESCRIPTION OF THE DRAWINGS

FIG. 1 is a schematic cross-sectional view of a semiconductor device according to a first embodiment.

FIG. 2 is a flowchart of a method for manufacturing the semiconductor device according to the first embodiment.

FIG. 3 is a schematic view of a base material forming step according to the first embodiment.

FIG. 4 is a schematic view of an ion implanting step according to the first embodiment.

FIG. 5 is a schematic view of a trench forming step according to the first embodiment.

FIG. 6 is a schematic view of a first film formation step according to the first embodiment.

FIG. 7 is a schematic view of an inhibitor adsorbing step in a second film formation step according to the first embodiment.

FIG. 8 is a schematic view of a precursor adsorbing step in the second film formation step according to the first embodiment.

FIG. 9 is a schematic view of a film forming step in the second film formation step according to the first embodiment.

FIG. 10 is a schematic view of a first oxidizing step according to the first embodiment.

FIG. 11 is a schematic view of an etching step according to the first embodiment.

FIG. 12 is a schematic view of a second oxidizing step according to the first embodiment.

FIG. 13 is a schematic view of an electrode forming step according to the first embodiment.

FIG. 14 is a schematic view of an interlayer insulating film forming step according to the first embodiment.

FIG. 15 is a schematic view of the first oxidizing step according to a modification example which can be employed in the first embodiment.

FIG. 16 is a schematic view of the second film formation step according to a modification example which can be employed in the first embodiment.

FIG. 17 is a part of a flowchart of a method for manufacturing the semiconductor device according to a second embodiment.

FIG. 18 is a schematic view of a precursor adsorbing step in a second film formation step according to the second embodiment.

FIG. 19 is a schematic view of a film forming step in the second film formation step according to the second embodiment.

FIG. 20 is a schematic view of a first oxidizing step according to the second embodiment.

FIG. 21 is a schematic view of first and second etching steps according to the second embodiment.

FIG. 22 is a schematic view of a third etching step according to the second embodiment.

FIG. 23 is a schematic view of a third film formation step according to the second embodiment.

FIG. 24 is a schematic view of a second oxidizing step according to the second embodiment.

### DETAILED DESCRIPTION

A method for manufacturing a semiconductor device according to an embodiment has a first film formation step, a second film formation step, and an oxidizing step. In the first film formation step, a first coating film made of silicon is formed on a surface of a base material made of silicon carbide. In the second film formation step, a second coating film is formed on a surface of the first coating film. In the oxidizing step, the first coating film is thermally oxidized from a surface side to form a third coating film. In the second film formation step, on a part of the first coating film, the second coating film is not formed, and the part is exposed. Alternatively, in the second film formation step, a film thickness of the second coating film formed on the part of the first coating film is smaller than a film thickness of the second coating film formed on a different part.

Hereinafter, the method for manufacturing a semiconductor device according to the embodiment will be described with reference to the drawings.

In this specification, the concepts of “up” and “down” are not necessarily terms indicating a relationship with the direction of gravity.

In the following description, the notations n, n⁻, p, and p⁻ represent relative levels of impurity concentration in respective types of conductivity. That is, n⁻ indicates that the n-type impurity concentration is relatively lower than that of n. In addition, p⁻ indicates that the p-type impurity concentration is relatively lower than that of p. The n⁻ -type may also be simply described as an n-type, and the p-type may also be simply described as a p-type.

### First Embodiment

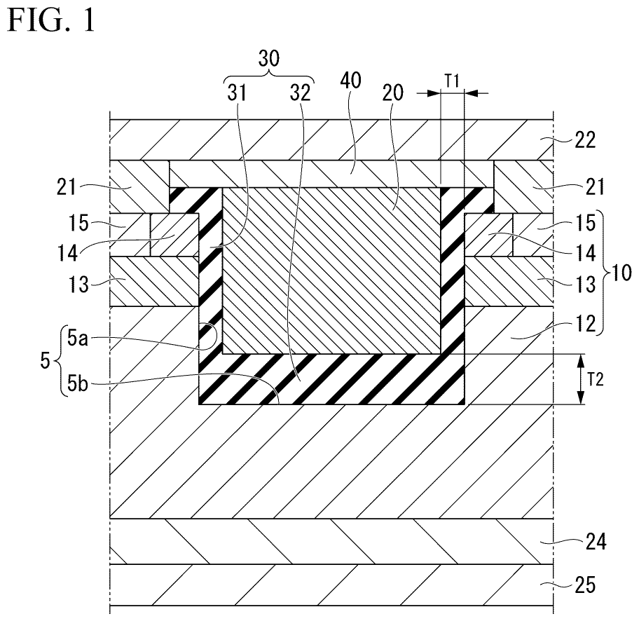

FIG. 1 is a schematic cross-sectional view of a semiconductor device 1 according to a first embodiment. The semiconductor device 1 according to the present embodiment is a trench-type metal-oxide-semiconductor field-effect transistor (MOSFET, which will hereinafter be referred to as a MOSFET).

The semiconductor device 1 has a base material 10, an insulating film 30 (gate insulating film), a gate electrode 20, an interlayer insulating film 40, a source electrode 21, a drain electrode 24, a source wiring 22, and a protective electrode 25.

The base material 10 is made of silicon carbide (SiC). The silicon carbide constituting the base material 10 preferably has a hexagonal crystal structure, and more preferably has a poly-type 4H. The base material 10 is formed by epitaxially growing silicon carbide on a single crystal substrate made of silicon carbide. Silicon carbide (SiC) has a dielectric breakdown field strength which is approximately ten times greater than that of silicon (Si). For this reason, the impurity concentration can be increased while the withstand voltage is maintained using silicon carbide for the base material 10 of the semiconductor device 1, and therefore a low-loss, low-resistance, and high-power MOSFET can be constituted. The base material 10 has an n-layer 12, a p-type body layer 13, an n-region 14, and a contact region 15.

Since a donor is added, the n-layer 12 has n-type conductivity. The p-type body layer 13 is provided on the n⁻-layer 12. The n-region 14 has n-type conductivity. The n-layer 12 has n-type conductivity. The n-region 14 is provided on the p-type body layer 13. The n-region 14 is separated from the n-layer 12 by the p-type body layer 13. The n-region 14 has an n-type impurity concentration which is relatively higher than that of the n⁻-layer 12. The contact region 15 has p-type conductivity. The p-type body layer 13 has p⁻-type conductivity. The contact region 15 is formed on a part of the p-type body layer 13 in a manner of being connected to the p-type body layer 13. The contact region 15 has a p-type impurity concentration which is relatively higher than that of the p-type body layer 13.

The base material 10 has a trench 5. The trench 5 opens upward. Inner side surfaces of the trench 5 include a bottom surface 5b, and a side wall surface 5a extending upward from the bottom surface 5b. The bottom surface 5b of the trench 5 is disposed in the n⁻-layer 12. The side wall surface 5a of the trench 5 extends to the n⁻-layer 12 through the p-type body layer 13 from a top surface of the n-region 14.

The inner side surfaces, that is, the side wall surface 5a and the bottom surface 5b of the trench 5 are coated with insulating film 30. The insulating film 30 has a side wall film 31 provided on the side wall surface 5a of the trench 5, and a bottom film 32 provided on the bottom surface 5b. The side wall film 31 extends upward from the bottom film 32. A film thickness T2 of the bottom film 32 is larger than a film thickness T1 of the side wall film 31. When the semiconductor device 1 is driven, an electric field is likely to concentrate at a corner portion between the bottom surface 5b and the side wall surface 5a of the trench 5, and the withstand voltage at this part is likely to cause a problem. According to the present embodiment, while the film thickness T1 of the side wall film 31 is made relatively thin to decrease the threshold voltage and the channel resistance of the semiconductor device 1, the film thickness T2 of the bottom film 32 is made relatively thick to increase the withstand voltage at the corner portion so that the semiconductor device 1 having excellent insulating characteristics can be constituted. For example, the film thickness T2 of the bottom film 32 is preferably larger than the film thickness T1 of the side wall film 31 by 1 nm or greater (T2−T1≥1 nm), and is more preferably larger by 10 nm or greater (T2−T1>10 nm).

The gate electrode 20 is embedded in the trench 5. The insulating film 30 is interposed between the gate electrode 20 and the inner side surfaces of the trench 5. That is, the insulating film 30 partitions the base material 10 and the gate electrode 20 inside the trench 5. The gate electrode 20 faces a surface of the p-type body layer 13 with the insulating film 30 therebetween. A top surface of the gate electrode 20 is at almost the same height as the top surface of a part in the insulating film 30 positioned on the top surface of the n-region 14. The interlayer insulating film 40 is provided so as to cover a part of the insulating film 30 extending upward beyond the top surface of the n-region 14, and the gate electrode 20.

The source electrode 21 penetrates the interlayer insulating film 40 and the insulating film 30, and comes into contact with each of the n-region 14 and the contact region 15. The source wiring 22 is provided on the source electrode 21 and the interlayer insulating film 40 in a manner of being in contact with the source electrode 21. The drain electrode 24 is provided on a surface of the base material 10 opposite to the surface on which the trench 5 is provided. The drain electrode 24 is coated with the protective electrode 25.

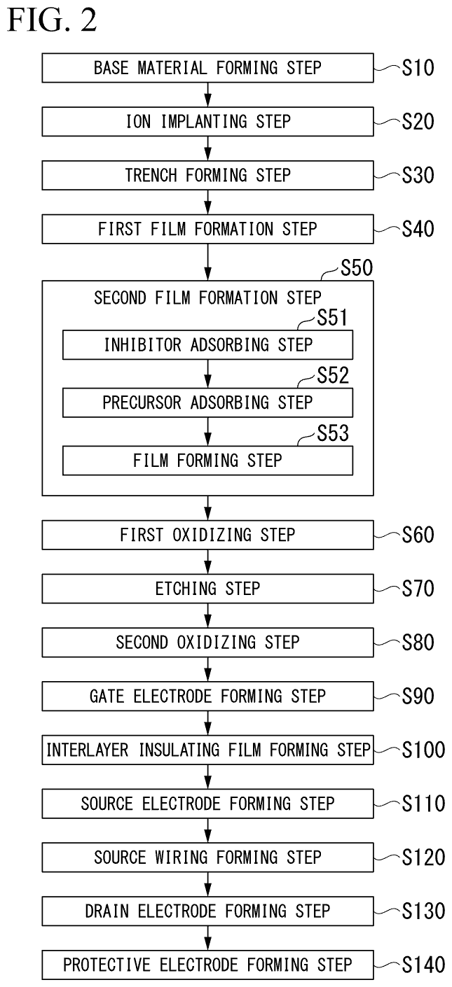

Next, a method for manufacturing the semiconductor device 1 will be described. FIG. 2 is a flowchart showing each of steps of a method for manufacturing the semiconductor device 1 according to the present embodiment. The method for manufacturing the semiconductor device 1 according to the present embodiment has a base material forming step S10, an ion implanting step S20, a trench forming step S30, a first film formation step S40, a second film formation step S50, a first oxidizing step (oxidizing step) S60, an etching step S70, a second oxidizing step (oxide coating film forming step) S80, a gate electrode forming step S90, an interlayer insulating film forming step S100, a source electrode forming step S110, a source wiring forming step S120, a drain electrode forming step S130, and a protective electrode forming step S140.

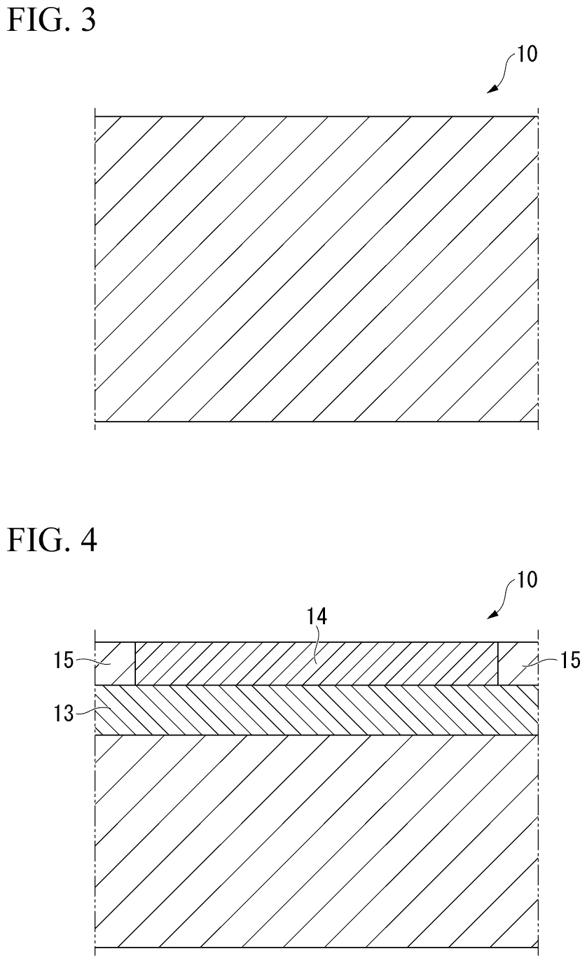

FIG. 3 is a schematic view of the base material forming step S10 according to the present embodiment. In the base material forming step S10, for example, the base material 10 is manufactured by forming the n-layer 12, in which nitrogen (N) or phosphorous (P) is introduced into silicon carbide, by epitaxial growth on a single crystal substrate made of silicon carbide that has been prepared in advance. For example, the single crystal substrate will be partially polished and removed in a final step, but this is not shown here in the diagrams.

FIG. 4 is a schematic view of the ion implanting step S20 according to the present embodiment. In the ion implanting step S20, the p-type body layer 13, the n-region 14, and the contact region 15 are formed. In the ion implanting step S20, in order to form the p-type body layer 13, ion implantation of an acceptor such as aluminum (Al) is performed from a top surface of the base material 10. In the ion implanting step S20, subsequently, in order to form the n-region 14, ion implantation of a donor such as phosphorous (P) is performed from the top surface of the base material 10. Accordingly, the base material 10 having the n-layer 12, the p-type body layer 13, and the n-region 14 is formed. In the ion implanting step S20, subsequently, in order to form the contact region 15, ion implantation of an acceptor such as aluminum is performed. In the manufacturing method according to the present embodiment, instead of the ion implanting step S20, the p-type body layer 13 and the n-region 14 may be formed using epitaxial growth accompanied by addition of impurities.

Next, activation heat treatment is performed to activate the impurities added by ion implantation. The temperature of this heat treatment is preferably 1,500° C. to 1,900° C., and it is approximately 1,700° C., for example. The heat treatment time is approximately 30 minutes, for example. The heat treatment atmosphere is preferably an inert gas atmosphere, and it is an argon (Ar) atmosphere, for example.

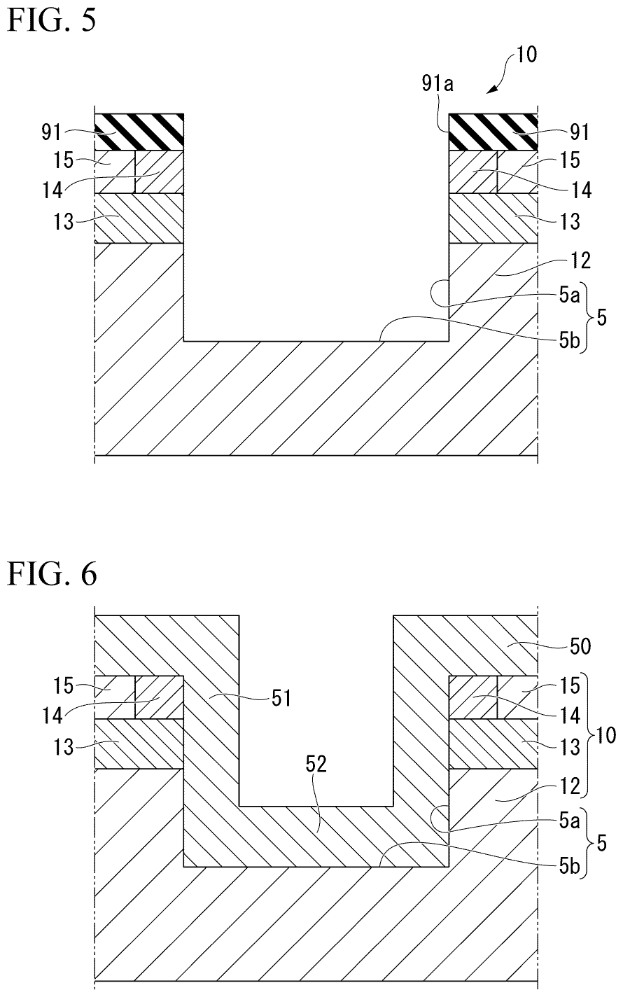

FIG. 5 is a schematic view of the trench forming step S30 according to the present embodiment. In the trench forming step S30, a trench is formed in the base material 10 made of silicon carbide. In the trench forming step S30, first, a mask 91 having an opening portion 91a partially exposing the n-region 14 is formed on the base material 10. The opening portion 91a of the mask 91 is formed correspondingly to the position of the trench 5. In the opening portion 91a of the mask 91, a part of each of the n-region 14, the p-type body layer 13, and the n-layer 12 is removed by etching. Accordingly, the trench 5 is formed in the base material 10. The mask 91 is removed after the trench 5 is formed.

FIG. 6 is a schematic view of the first film formation step S40 according to the present embodiment. The first film formation step S40 is a step of forming a silicon coating film (first coating film) 50 on the inner side surfaces of the trench 5. The silicon coating film 50 is made of silicon. In the first film formation step S40, for example, the silicon coating film 50 is formed by a low-pressure CVD method (LP-CVD).

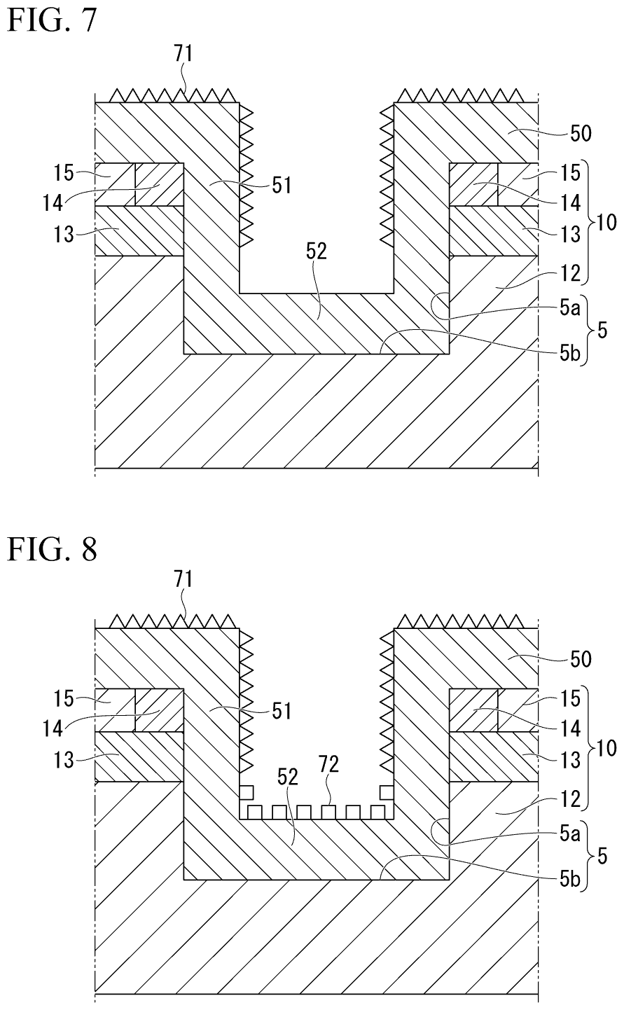

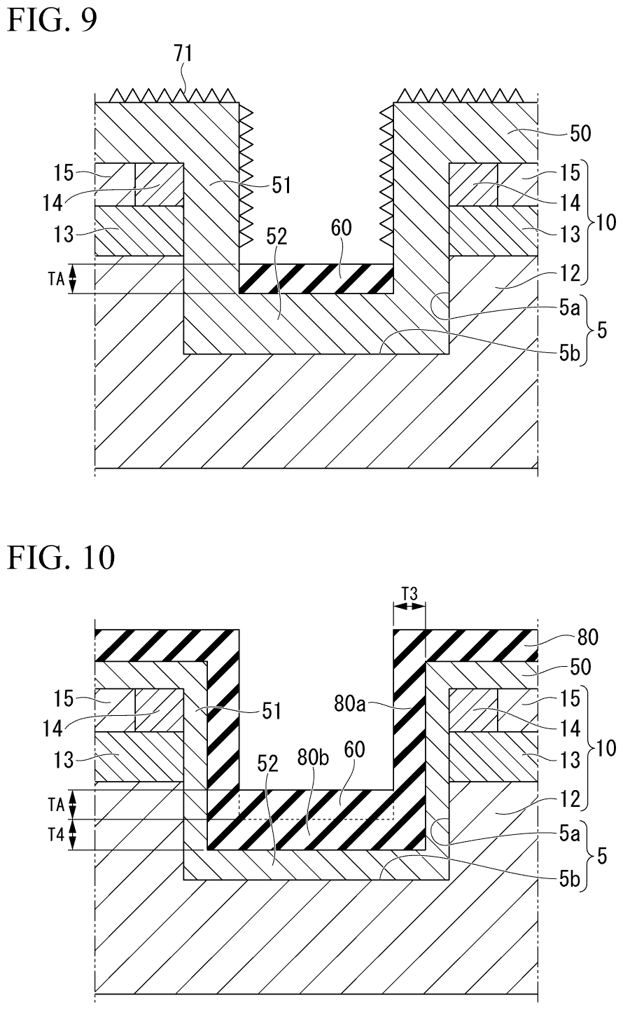

FIGS. 7 to 9 are schematic views showing each of steps of the second film formation step S50 according to the present embodiment. The second film formation step S50 according to the present embodiment has an inhibitor adsorbing step S51 (FIG. 7), a precursor adsorbing step S52 (FIG. 8), and a film forming step S53 (FIG. 9). The second film formation step S50 is a step of forming a barrier coating film (second coating film) 60 by atomic layer deposition (ALD, which will hereinafter be referred to as ALD) in a part on the silicon coating film 50 provided on the inner side surfaces of the trench 5. In the following description, in the silicon coating film 50, a region provided on the side wall surface 5a of the trench 5 will be referred to as a side wall coating film 51, and a region provided on the bottom surface 5b of the trench 5 will be referred to as a bottom coating film 52. In the second film formation step S50 according to the present embodiment, the barrier coating film 60 is formed only on the bottom coating film 52. In addition, in the present embodiment, the barrier coating film 60 is made of silicon oxide (SiO₂). However, the material of the barrier coating film 60 is not limited to the present embodiment.

FIG. 7 is a schematic view of the inhibitor adsorbing step S51 according to the present embodiment. The inhibitor adsorbing step S51 is a step of causing the side wall coating film 51 to adsorb a factor inhibiting adsorption (which will hereinafter be referred to as an inhibitor 71) of a precursor 72 (refer to FIG. 8, which will be described below). In the method for manufacturing the semiconductor device 1 according to the present embodiment, examples of the inhibitor 71 include self-assembled monolayers (SAMs), small molecule inhibitors (SIMs), and surface termination using nitrogen atoms (N) or hydrogen atoms (H). In the inhibitor adsorbing step S51, the inhibitor 71 is formed on the silicon coating film 50 by CVD. More specifically, a gas containing the inhibitor 71 is introduced into a treatment chamber. After the inhibitor 71 is adsorbed, the gas containing the inhibitor 71 is exhausted from the treatment chamber.

In the inhibitor adsorbing step S51 according to the present embodiment, the pressure of the gas containing the inhibitor 71 and the introduction time of the gas are controlled to prevent the inhibitor 71 from reaching the innermost part on the inner side surfaces of the trench 5. For this reason, the inhibitor 71 is adsorbed to an upper region of the side wall coating film 51 on the inner side surfaces of the trench 5 and is not adsorbed to a lower region of the side wall coating film 51 and the bottom coating film 52.

FIG. 8 is a schematic view of the precursor adsorbing step S52 according to the present embodiment. In the precursor adsorbing step S52, a gas containing the precursor 72 is introduced into the treatment chamber. In the method for manufacturing the semiconductor device 1 according to the present embodiment, examples of the precursor 72 include TDMAS, Orthrus, 3DMAS, and SAM24. The precursor 72 is not adsorbed to a part on a surface of the silicon coating film 50 where the inhibitor 71 has been adsorbed. For this reason, the precursor 72 is selectively adsorbed to the lower region of the side wall coating film 51 and the bottom coating film 52 on the inner side surfaces of the trench 5. After the precursor 72 is adsorbed, the gas containing the precursor 72 is exhausted from the treatment chamber. When the precursor 72 is adsorbed, plasma may be generated.

FIG. 9 is a schematic view of the film forming step S53 according to the present embodiment. In the film forming step S53, a reactant gas containing a reactant serving as a base of the barrier coating film 60 is introduced into the treatment chamber. In the method for manufacturing the semiconductor device 1 according to the present embodiment, in the film forming step S53, SiO₂ is formed by causing O₃, radicals in plasma (for example, O radicals), or the like to react with adsorbed molecules (precursor). The reactant gas reacts with atoms of the precursor 72 only at the position where the precursor 72 has been adsorbed, thereby forming the barrier coating film 60 made of silicon oxide (SiO₂). For this reason, the barrier coating film 60 is formed only in the lower region of the side wall coating film 51 and the bottom coating film 52. After the barrier coating film 60 is formed, the reactant gas is exhausted from the treatment chamber.

By going through the second film formation step S50 described above, the barrier coating film 60 is formed only in the lower region of the side wall coating film 51 and the bottom coating film 52. That is, in the second film formation step, a part of the silicon coating film 50 (bottom coating film 52) provided on the inner side surfaces of the trench 5 is covered by the barrier coating film 60, and other parts of the silicon coating film 50 (side wall coating film 51) are exposed from the barrier coating film 60. For this reason, a coating film in which the silicon coating film 50 and the barrier coating film 60 are combined becomes locally thicker in a part where the barrier coating film 60 is formed. In the present embodiment, it is assumed that the barrier coating film 60 has a film thickness TA. When ALD is employed for the second film formation step S50, in consideration of the film formation speed of the ALD from the viewpoint of productivity, the film thickness TA of the barrier coating film 60 is preferably set to 300 nm or smaller, for example.

According to the present embodiment, ALD is employed in the second film formation step S50. In the ALD, since atomic layers can be subjected to film formation one by one, film formation of the barrier coating film 60 can be performed with reduced incorporation of impurities and with a stoichiometric composition. For this reason, film formation of the barrier coating film 60 having a film thickness which is uniform and controlled with high accuracy can be selectively performed in a part on the inner side surfaces of the trench 5 by employing ALD for the second film formation step S50. In addition, when ALD is employed in the second film formation step S50, since film formation on the side wall coating film 51 can be partially limited using an inhibitor or the like, a part of the silicon coating film 50 (side wall coating film 51) can be exposed. In the present embodiment, a case in which the barrier coating film 60 is not formed on the side wall coating film 51 in the second film formation step S50 has been described. However, as will be described in a modification example in the latter stage (FIG. 16), a thin barrier coating film 60A may be formed on the side wall coating film 51. In this case, it is favorable that the film thickness of the barrier coating film 60A formed on the side wall coating film 51 be smaller than the film thickness of the barrier coating film 60A formed on the bottom coating film 52.

FIG. 10 is a schematic view of the first oxidizing step S60 according to the present embodiment. The first oxidizing step S60 is a step of thermally oxidizing the silicon coating film 50 from the surface side to form a first oxide coating film 80 made of silicon oxide (SiO₂). In the first oxidizing step S60, the temperature, the time, the oxygen concentration, and the like are adjusted to thermally oxidize only a part on the surface side of the silicon coating film 50, thereby forming the first oxide coating film (third coating film) 80. This thermal oxidation is performed at a temperature at which silicon is thermally oxidized and silicon carbide is not substantially not thermally oxidized.

In the following description, in the first oxide coating film 80, a part formed on the side wall coating film 51 will be referred to as a first part 80a, and a part formed on the bottom coating film 52 will be referred to as a second part 80b. By going through the first oxidizing step S60, the first part 80a having a film thickness T3 is formed on the surface of the side wall coating film 51. In addition, the second part 80b having a film thickness T4 is formed on a side of the interface between the bottom coating film 52 and the barrier coating film 60. Since the thermal oxidation of the bottom coating film 52 proceeds below the first oxide coating film 80, it proceeds slightly slower than the thermal oxidation of the side wall coating film 51. Therefore, the film thickness T4 of the second part 80b of the first oxide coating film 80 becomes slightly smaller than the film thickness T3 of the first part 80a.

By going through the first oxidizing step S60, a coating film made of silicon oxide (SiO₂) constituted of only the first oxide coating film 80 (first part 80a) having the film thickness T3 is formed on the side wall coating film 51. On the other hand, on the bottom coating film 52 after the first oxidizing step S60, a laminated coating film in which the barrier coating film 60 having the film thickness TA and the first oxide coating film 80 (second part 80b) having the film thickness T4 are laminated is formed. Here, the sum of the film thicknesses of the barrier coating film 60 and the first oxide coating film 80 (TA+T4) on the bottom coating film 52 is larger than the film thickness T3 of the first oxide coating film 80 on the side wall coating film 51 (TA+T4>T3). For this reason, in the oxide coating film on the silicon coating film 50, the film thickness (TA+T4) of a part formed on the bottom surface 5b of the trench 5 becomes larger than the film thickness T3 of a part formed on the side wall surface 5a.

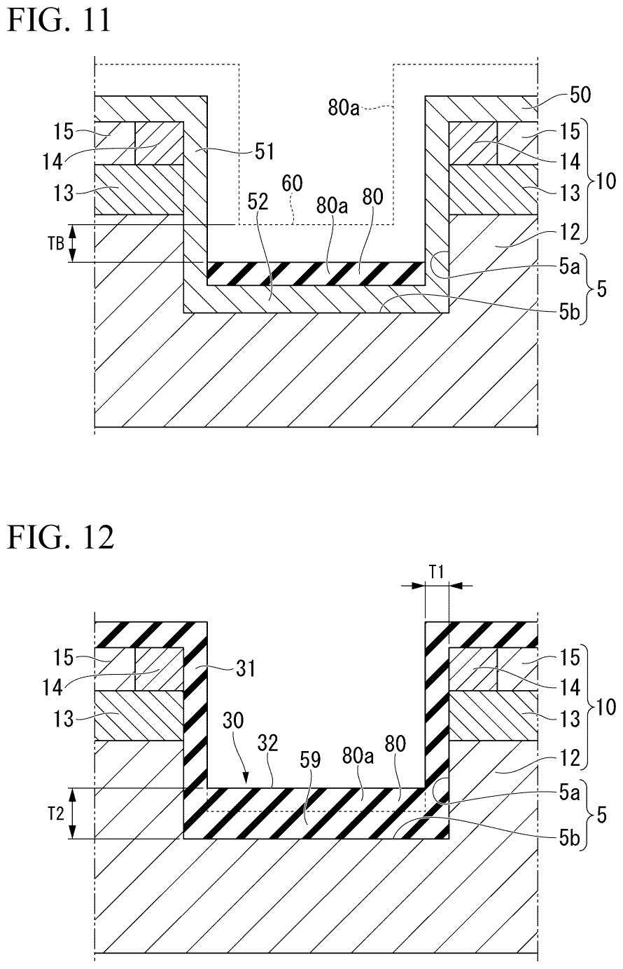

FIG. 11 is a schematic view of the etching step S70 according to the present embodiment. The etching step S70 is a step of removing the barrier coating film 60 and a part of the first oxide coating film 80 by etching. For example, the etching step S70 can be performed by various means, such as wet etching using a hydrofluoric acid, chemical dry etching, and reactive ion etching (RIE).

In the etching step S70 according to the present embodiment, the oxide coating film formed on the surface of the base material 10 is removed from the surface side by a predetermined film thickness. As shown in FIG. 11, a film thickness TB removed in the etching step S70 is larger than the film thickness T3 of the first part 80a and smaller than the sum of the film thicknesses (TA+T4) of the barrier coating film 60 and the second part 80b (T3<TB<TA+T4). For this reason, only the first part 80a of the first oxide coating film 80 positioned on the bottom surface 5b remains on the inner side surfaces of the trench 5 after the etching step S70, and the first part 80a on the side wall surface 5a is removed.

The film thickness TB removed in the etching step S70 is preferably larger than the film thickness TA of the barrier coating film 60 (TB>TA). Accordingly, a situation in which an oxide coating film derived from the barrier coating film 60 remains on the bottom surface 5b can be curbed, and only the oxide coating film formed by thermal oxidation can be caused to remain. Therefore, the uniformity of crystal in the insulating film 30 can be enhanced. The barrier coating film 60 does not necessarily have to be completely removed, and it may be caused to remain.

FIG. 12 is a schematic view of the second oxidizing step S80 according to the present embodiment. The second oxidizing step S80 is a step of thermally oxidizing the entire silicon coating film 50 remaining after the first oxidizing step S60 and the etching step S70 to form the insulating film 30. That is, the second oxidizing step S80 is a step of forming the insulating film (fourth coating film) 30 made of silicon oxide on the inner side surfaces of the trench 5. This thermal oxidation is performed at a temperature at which silicon is thermally oxidized and silicon carbide is not substantially not thermally oxidized.

By going through the second oxidizing step S80, the side wall coating film 51 and the bottom coating film 52 of the silicon coating film 50 are oxidized, and a second oxide coating film 59 derived from the silicon coating film 50 is formed on the inner side surfaces of the trench 5. The second oxide coating film 59 derived from the silicon coating film 50 and the first oxide coating film 80 formed on the second oxide coating film 59 combine and constitute the insulating film 30 on the inner side surfaces of the trench 5. As described above, since the first oxide coating film 80 remains only on the bottom surface 5b of the trench 5, the bottom film 32 of the insulating film 30 is constituted of the second oxide coating film 59 derived from the silicon coating film 50 and the first oxide coating film 80. On the other hand, the side wall film 31 of the insulating film 30 is constituted of only the second oxide coating film 59 derived from the silicon coating film 50. For this reason, in the insulating film 30, the film thickness T2 of the bottom film 32 becomes larger than the film thickness T1 of the side wall film 31.

FIG. 13 is a schematic view of the gate electrode forming step S90 according to the present embodiment. In the gate electrode forming step S90, the gate electrode 20 is formed inside the trench 5 and on the insulating film 30. Regarding a method for forming the gate electrode 20, for example, film formation of a conductor or doped polysilicon and chemical mechanical polishing (CMP) can be performed.

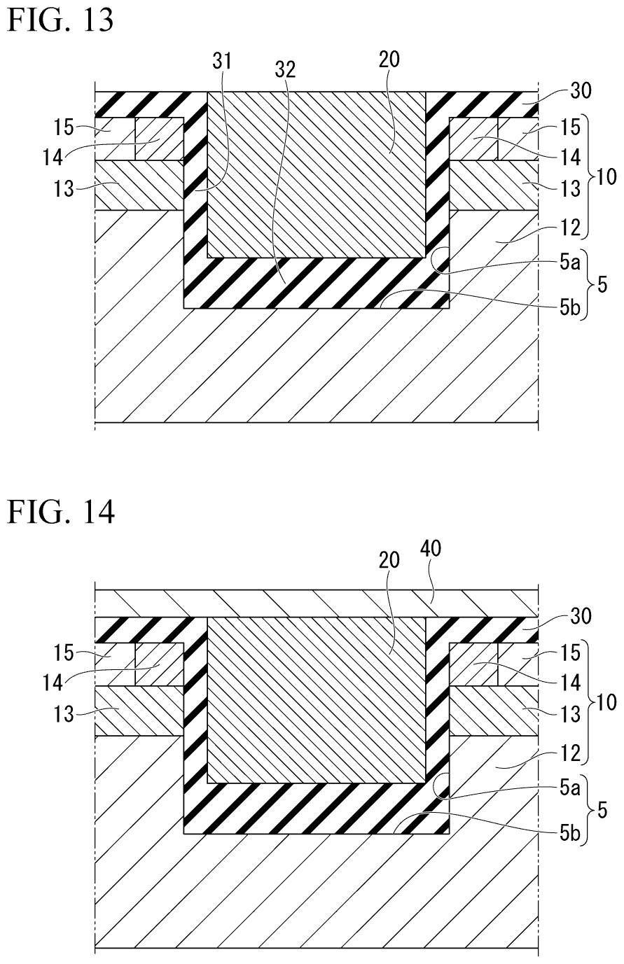

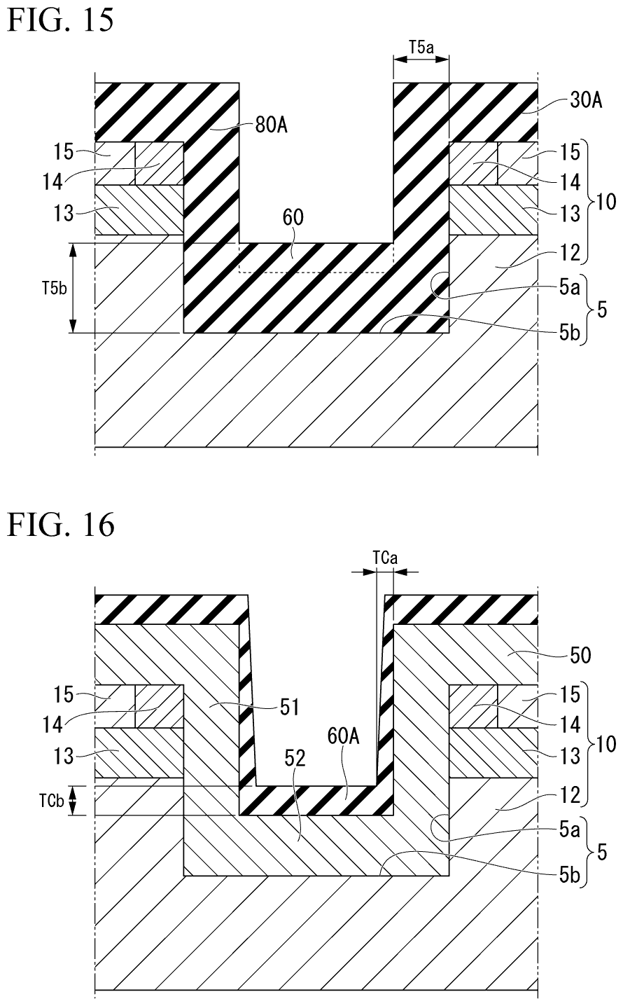

FIG. 14 is a schematic view of the interlayer insulating film forming step S100 according to the present embodiment. In the interlayer insulating film forming step S100, the interlayer insulating film 40 is formed on the gate electrode 20 and the insulating film 30 in a manner of covering the exposed surface of the gate electrode 20.

Subsequently, although they are not specifically shown in the diagrams, the source electrode forming step, the source wiring forming step, the drain electrode forming step, and the protective electrode forming step are performed, and as shown in FIG. 1, the source electrode 21, the source wiring 22, the drain electrode 24, and the protective electrode 25 are formed in this order. The source electrode 21 is formed after an opening portion is formed in the interlayer insulating film 40 and the insulating film by etching to expose the n-region 14 and the contact region 15.

By going through the foregoing steps, the semiconductor device 1 having the insulating film 30 in which the film thickness T2 on the bottom surface 5b of the trench is larger than the film thickness T1 on the side wall surface 5a can be manufactured.

Next, a first modification example which can be employed in the present embodiment will be described.

In the method for manufacturing the semiconductor device 1 according to the present embodiment, only a part of the silicon coating film 50 is oxidized from the surface side in the first oxidizing step S60, and the oxidized part is removed in the subsequent etching step S70. However, in the first oxidizing step S60, the entire silicon coating film 50 may be oxidized and utilized as a part of the insulating film 30 as it is. FIG. 15 is a schematic view of the first oxidizing step S60 according to a modification example which can be employed in the present embodiment. In the first oxidizing step S60 according to the present modification example, the entire silicon coating film 50 is thermally oxidized to form a first oxide coating film 80A. In addition, the coating film constituted of the barrier coating film 60 and the first oxide coating film 80A serves as an insulating film 30A according to the modification example. In the insulating film 30A according to the present modification example, only the first oxide coating film 80A is disposed on the side wall surface 5a of the trench, whereas the barrier coating film 60 is disposed on the bottom surface 5b in addition to the first oxide coating film 80A. For this reason, in the insulating film 30A, a film thickness T5b on the bottom surface 5b can be made larger than a film thickness T5a on the side wall surface 5a. After the first oxidizing step S60 according to the present modification example is performed, steps following the gate electrode forming step S90 are performed through the procedure described above without performing the etching step S70 and the second oxidizing step S80. That is, according to the present modification example, some of the steps for forming the insulating film 30A can be omitted so that the steps of manufacturing the semiconductor device 1 can be simplified. In the embodiment described above, the barrier coating film 60 is removed in the etching step S70, and the thickness of the insulating film 30 is ensured by thermal oxidation performed separately. Accordingly, in the embodiment described above, the uniformity of crystal in the insulating film 30 is enhanced by utilizing only the oxide coating film formed by thermal oxidation as the insulating film 30.

Moreover, a second modification example which can be employed in the present embodiment will be described.

In addition, in the present embodiment, a case in which only the silicon coating film 50 which has remained without being oxidized in the first oxidizing step S60 (FIG. 10) is thermally oxidized in the second oxidizing step S80 (FIG. 12) and used as the insulating film 30 has been described. However, after the etching step S70 (FIG. 11), a new coating film made of silicon may be formed on the silicon coating film 50 and the first oxide coating film 80. In this case, the new silicon coating film is thermally oxidized together with the silicon coating film 50 in the second oxidizing step S80 and constitutes the insulating film 30 together with the first oxide coating film 80 remaining after the etching step S70 (FIG. 11). In this case, the insulating film 30 which is thicker than that in the present embodiment can be formed.

Moreover, a third modification example which can be employed in the present embodiment will be described.

In addition, in the present embodiment, a case in which ALD is employed in the second film formation step S50 has been described. However, regarding a modification example of the second film formation step S50, a case of employing CVD can also be assumed. FIG. 16 is a schematic view of the second film formation step S50 according to a modification example. Examples of CVD which can be employed for the second film formation step S50 according to the present modification example include high density plasma chemical vapor deposition (HDPCVD), selective area chemical vapor deposition (SACVD), and plasma-enhanced chemical vapor deposition (PECVD). The barrier coating film 60A according to the present modification example is formed not only on the bottom surface 5b of the trench 5 but also on the side wall surface 5a, but a film thickness TCa of the barrier coating film 60A on the side wall surface 5a becomes smaller than a film thickness TCb on the bottom surface 5b. That is, in the second film formation step S50, the film thickness TCa of the barrier coating film 60A formed on a part of the silicon coating film 50 (side wall coating film 51) is smaller than the film thickness TCb of the barrier coating film 60A formed on other parts (bottom coating film 52). In the present modification example as well, similar to the embodiment described above, the entire barrier coating film 60A is removed in the etching step S70 after the silicon coating film 50 is thermally oxidized to form the first oxide coating film 80 in the first oxidizing step S60. Similar to the embodiment described above, in the etching step S70, the first oxide coating film 80 on the bottom surface 5b can be caused to remain depending on the difference in the film thickness of the barrier coating film 60A.

Each of the constitutions according to the first embodiment will be summarized.

The method for manufacturing the semiconductor device 1 according to the present embodiment has the first film formation step S40, the second film formation step S50, and the first oxidizing step (oxidizing step) S60. The first film formation step S40 is a step of forming the silicon coating film 50 made of silicon (Si) on the surface of the base material 10 made of silicon carbide (SiC). The second film formation step S50 is a step of forming the barrier coating film 60 in a part on the surface of the silicon coating film 50. The first oxidizing step S60 is a step of thermally oxidizing the silicon coating film 50 from the surface side to form the first oxide coating film 80. In the second film formation step S50, the barrier coating film 60 is not formed on a part of the silicon coating film 50 and the part is exposed. Alternatively, the film thickness of the barrier coating film 60 formed on a part of the silicon coating film 50 is smaller than the film thickness of the barrier coating film 60 formed on other parts.

According to the constitutions described above, after the first oxidizing step S60 is performed, the thickness of a composite coating film formed by the barrier coating film 60 and the first oxide coating film 80 can be locally changed on the surface of the base material 10. In the embodiment described above, by etching this composite coating film (etching step S70), a part of the first oxide coating film 80 is caused to remain to form the locally thick insulating film 30. In addition, in the modification example described above (refer to FIG. 15), by utilizing this composite coating film as the insulating film 30A as it is, the locally thick insulating film 30A in which the barrier coating film 60 and the first oxide coating film 80 are laminated is formed. In this manner, according to the constitutions described above, by selectively adjusting the thickness of the barrier coating film 60, the insulating films 30 and 30A whose disposition and thickness are freely adjusted can be formed. Consequently, only the insulating films 30 and 30A in a part where the insulating performance needs to be enhanced are formed thick, and therefore the semiconductor device 1 which is small in size and has excellent withstand voltage can be manufactured. According to the constitutions described above, regarding the insulating film 30A, the insulating film 30 can be constituted using an oxide coating film obtained by thermally oxidizing a coating film subjected to film formation of silicon, or an oxide coating film formed by ALD. That is, according to the constitutions described above, a coating film subjected to film formation using CVD is not used as the insulating films 30 and 30A. For this reason, compared to when an insulating film is formed by CVD, the locally thick insulating films 30 and 30A in which incorporation of impurities is curbed can be formed.

In the constitutions described above, the first oxidizing step S60 may be a step of thermally oxidizing only a part of the silicon coating film 50 to form the first oxide coating film 80 (FIG. 10) or may be a step of thermally oxidizing the entire silicon coating film 50 to form the first oxide coating film 80A (refer to FIG. 15).

The method for manufacturing the semiconductor device 1 according to the present embodiment has the etching step S70 and the second oxidizing step (oxide coating film forming step) S80. The etching step S70 is a step of etching the barrier coating film 60 and at least a part of the first oxide coating film 80. The second oxidizing step S80 is a step of forming the insulating film (fourth coating film) 30 made of silicon oxide (SiO₂) on the surface of the base material 10.

According to the constitutions described above, the barrier coating film 60 is removed by etching in the etching step S70, and then the insulating film 30 can be formed in the second oxidizing step S80. Therefore, the insulating film 30 can be formed only by thermal oxidation without causing the coating film derived from the barrier coating film 60 to remain in the insulating film 30, and therefore the uniformity of crystal in the insulating film 30 can be enhanced.

The method for manufacturing the semiconductor device 1 according to the present embodiment has the trench forming step S30 of forming the trench 5 in the base material 10 before the first film formation step S40. The part of the silicon coating film 50 described above, in which the barrier coating film 60 is not formed (or only a thin barrier coating film is formed), is a part subjected to film formation on the side wall surface 5a of the trench 5. In addition, other parts of the silicon coating film 50 described above, in which the barrier coating film 60 is formed, are parts formed on the bottom surface 5b of the trench 5. According to this constitution, the barrier coating film 60 can be formed only on the bottom surface 5b of the trench 5, or the barrier coating film 60 on the bottom surface 5b can be thicker than the barrier coating film 60 on the side wall surface 5a. Accordingly, for example, in the insulating films 30 and 30A, the insulating performance of the bottom film 32 can be further enhanced than the insulating performance of the thinly formed part (side wall film 31). When the semiconductor device 1 is a trench-type MOSFET, an electric field is likely to concentrate in the vicinity of the corner portion on the bottom surface 5b of the trench 5, and dielectric breakdown is likely to occur. By making the bottom film 32 of the insulating film 30 thicker than other parts as described in the present embodiment, the insulating characteristics of the trench-type MOSFET can be enhanced.

In the method for manufacturing the semiconductor device 1 according to the present embodiment, the barrier coating film 60 is formed of silicon oxide (SiO₂). According to this constitution, both the barrier coating film 60 and the first oxide coating film 80 are constituted using silicon oxide. For this reason, diffusion coefficients of oxygen in the barrier coating film 60 and the first oxide coating film 80 substantially coincide with each other so that an oxide coating film having a sufficient thickness can be formed below the barrier coating film 60 in the first oxidizing step S60. In addition, when the etching step S70 is performed, the barrier coating film 60 and the first oxide coating film 80 can be etched at the same time, and therefore simplified manufacturing steps can be achieved.

### Second Embodiment

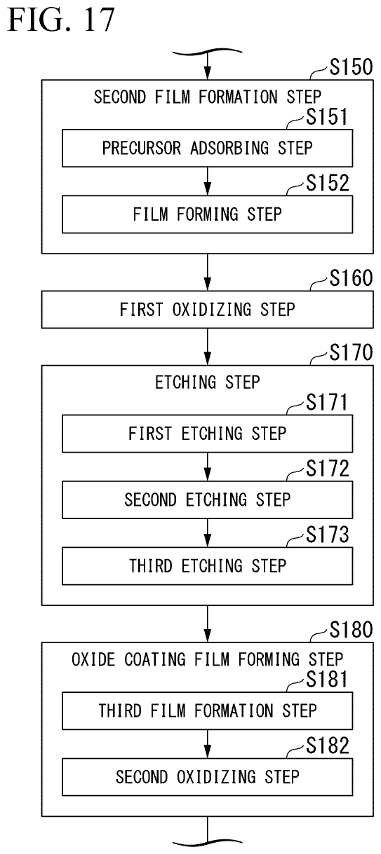

FIG. 17 is a flowchart showing some steps of a method for manufacturing the semiconductor device 1 according to a second embodiment. In description of each embodiment which will be described below, the same reference signs are applied to constituent elements having the same form as the embodiment which has already been described, and description thereof will be omitted.

As shown in FIG. 17, the second embodiment has a second film formation step S150, a first oxidizing step S160, an etching step S170, and an oxide coating film forming step S180. In the manufacturing method according to the second embodiment, description of constitutions similar to those in the manufacturing method according to the first embodiment will be omitted. That is, in the second embodiment, description of the base material forming step S10, the ion implanting step S20, the trench forming step S30, and the first film formation step S40 performed before each of the steps shown in FIG. 17, and description of the gate electrode forming step S90, the interlayer insulating film forming step S100, the source electrode forming step S110, the source wiring forming step S120, the drain electrode forming step S130, and the protective electrode forming step S140 performed after each of the steps shown in FIG. 17 will be omitted.

The second film formation step S150 according to the present embodiment has a precursor adsorbing step S151 and a film forming step S152. The second film formation step S150 is a step of forming a barrier coating film (second coating film) 160 by ALD in a part on the silicon coating film 50 provided on the inner side surfaces of the trench 5. In the present embodiment, the barrier coating film 160 is formed of silicon nitride (SiN).

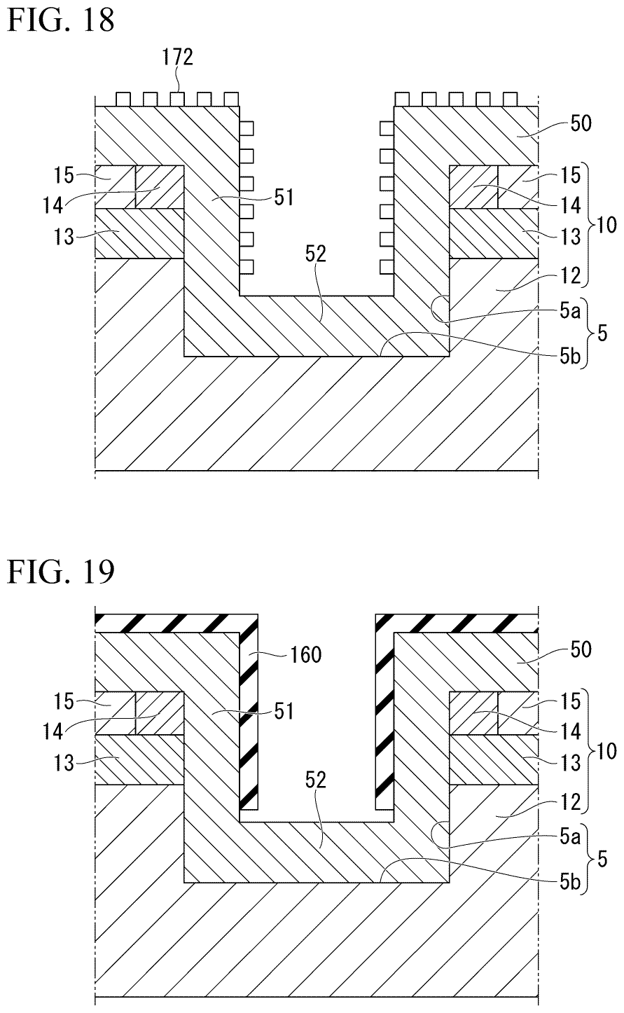

FIG. 18 is a schematic view of the precursor adsorbing step S151 according to the present embodiment. In the precursor adsorbing step S151, a gas containing a precursor 172 is introduced into the treatment chamber. Examples of the precursor 172 according to the present embodiment include chlorosilane, organic silane, and heterosilane. In addition, the gas containing the precursor 172 is exhausted from the inside of the treatment chamber before it sufficiently reaches the bottom surface 5b of the trench 5. Accordingly, in the precursor adsorbing step S151 according to the present embodiment, the precursor 172 is adsorbed to the side wall coating film 51 on the inner side surfaces of the trench 5 and is not adsorbed to the bottom coating film 52 and the side wall coating film 51 in the vicinity of the bottom coating film 52.

FIG. 19 is a schematic view of the film forming step S152 according to the present embodiment. In the film forming step S152, a reactant gas containing a reactant serving as a base of the barrier coating film 160 is introduced into the treatment chamber. Examples of the reactant gas include NH₃ plasma. The reactant gas reacts with atoms of the precursor 172 only at the position where the precursor 172 has been adsorbed, thereby forming the barrier coating film 160. For this reason, the barrier coating film 160 is formed only in the upper region of the side wall coating film 51 inside the trench 5. Ater the barrier coating film 160 is formed, the reactant gas is exhausted from the treatment chamber.

By going through the second film formation step S150 described above, the barrier coating film 160 made of silicon nitride (SiN) is formed only in the upper region of the side wall coating film 51 inside the trench 5. That is, in the second film formation step S150, the barrier coating film 160 is not formed on a part of the silicon coating film 50 (bottom coating film 52), and the part is exposed.

Regarding a modification example of the second film formation step S150, after the barrier coating film 160 is subjected to film formation by ALD with a uniform film thickness on the entire inner side surfaces including the bottom surface 5b of the trench 5, only the barrier coating film 160 on the bottom coating film 52 may be removed by reactive ion etching (RIE). In this case, in the precursor adsorbing step, the precursor is adsorbed to the entire inner side surfaces of the trench 5. Accordingly, in the film forming step, the barrier coating film is formed on the entire inner side surfaces of the trench 5.

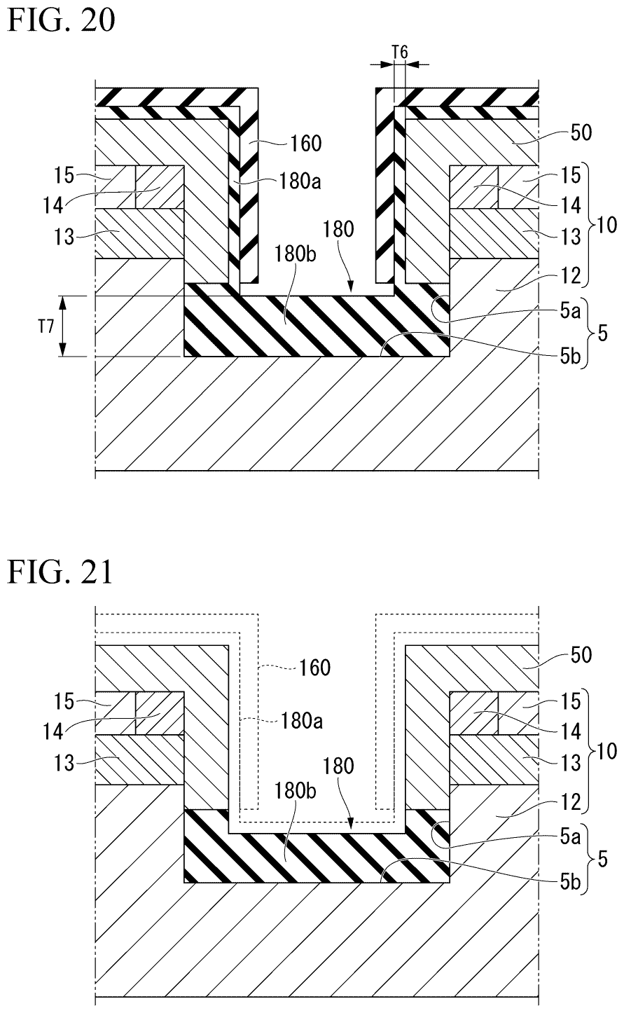

FIG. 20 is a schematic view of the first oxidizing step S160 according to the present embodiment. The first oxidizing step S160 is a step of thermally oxidizing the silicon coating film 50 from the surface side to form a first oxide coating film (third coating film) 180. The silicon nitride (SiN) constituting the barrier coating film 160 has a smaller diffusion coefficient of oxygen than silicon oxide (SiO₂). For this reason, in the first oxidizing step S160, thermal oxidation proceeds slower below the barrier coating film 160. Therefore, in the first oxidizing step S160, a film thickness T6 of a first part 180a in the first oxide coating film 180 formed below the barrier coating film 160 becomes smaller than a film thickness T7 of a second part 180b exposed from the barrier coating film 160. In the present embodiment, in the silicon coating film 50 below the barrier coating film 60, only a part on the boundary side between the silicon coating film 50 and the barrier coating film 60 becomes the first oxide coating film 180. On the other hand, the silicon coating film 50 exposed from the barrier coating film 160 is oxidized in its entirety in the thickness direction and becomes the first oxide coating film 180.

In the present embodiment, a case in which silicon nitride is used for the barrier coating film 160 has been described. However, as long as the diffusion coefficient of oxygen in the barrier coating film 160 is smaller than that of silicon oxide, a similar first oxide coating film 180 can be formed.

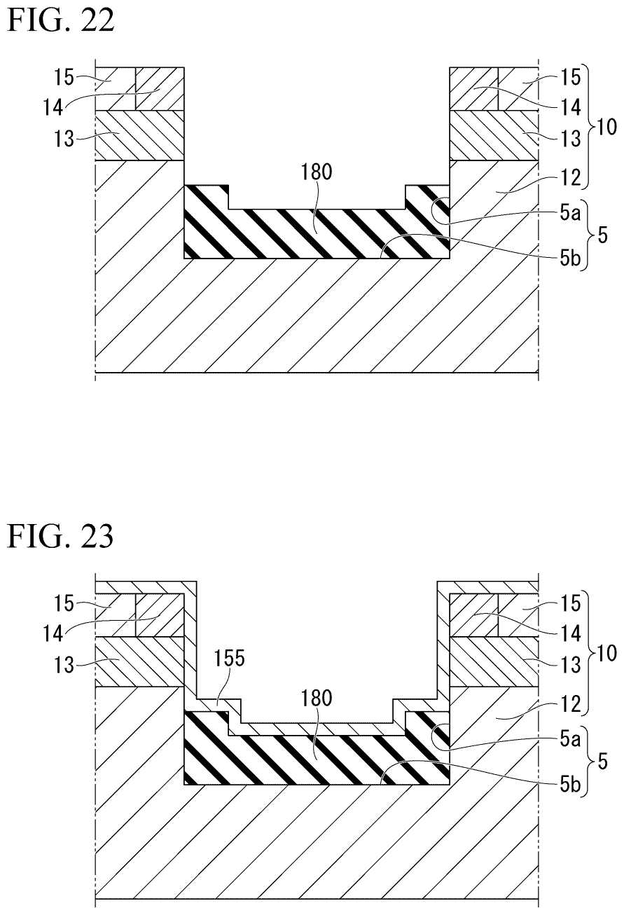

FIGS. 21 and 22 are schematic views of the etching step S170 according to the present embodiment. The etching step S170 according to the present embodiment has a first etching step S171 shown in FIG. 21, a second etching step S172, and a third etching step S173 shown in FIG. 22. As shown in FIG. 21, the first etching step S171 and the second etching step S172 are steps of removing the barrier coating film 160 and a part of the first oxide coating film 180 by etching. Moreover, as shown in FIG. 22, the third etching step S173 is a step of removing the silicon coating film 50 by etching. That is, in the etching step S170 according to the present embodiment, etching for removing the barrier coating film 160 made of silicon nitride, etching for removing the first oxide coating film 180 made of silicon oxide, and etching for removing the silicon coating film 50 made of silicon are performed in stages.

As shown in FIG. 21, in the first etching step S171, the entire barrier coating film 160 is removed. In addition, in the second etching step S172, the first part 180a of the first oxide coating film 180 is etched by the film thickness T6. For this reason, on the inner side surfaces of the trench 5 after the second etching step S172, only the first oxide coating film 180 remains in the lower region on the side wall surface 5a and on the bottom surface 5b, and only the silicon coating film 50 remains in the upper region on the side wall surface 5a. As shown in FIG. 22, in the third etching step S173, the entire silicon coating film 50 is removed. Only the first oxide coating film 180 remains inside the trench 5 after the etching step S170.

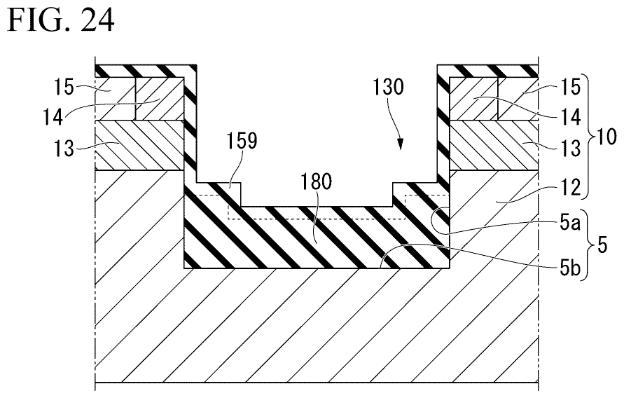

FIGS. 23 and 24 are schematic views of the oxide coating film forming step S180. The oxide coating film forming step S180 is a step of forming an insulating film (fourth coating film) 130 made of silicon oxide (SiO₂) on the surface of the base material 10. The oxide coating film forming step S180 according to the present embodiment has a third film formation step S181 shown in FIG. 23 and a second oxidizing step S182 shown in FIG. 24.

As shown in FIG. 23, the third film formation step S181 is a step of performing film formation of a silicon coating film 155 made of silicon (Si) and having a uniform film thickness on the surface of the base material 10. In the third film formation step S181, for example, the silicon coating film 155 is formed by the low-pressure CVD method (LP-CVD).

As shown in FIG. 24, the second oxidizing step S182 is a step of thermally oxidizing the silicon coating film 155 which has been subjected to film formation in the third film formation step S181 to form a second oxide coating film 159. The second oxidizing step S182 is performed at a temperature at which silicon is thermally oxidized and silicon carbide is not substantially not thermally oxidized. By going through the second oxidizing step S182, the first oxide coating film 180 and the second oxide coating film 159 derived from the silicon coating film 155 are disposed on the inner side surfaces of the trench 5. The first oxide coating film 180 and the second oxide coating film 159 constitute the insulating film 130. As described above, the first oxide coating film 180 remains only on the bottom surface 5b of the trench 5 and the side wall surface 5a in the vicinity of the bottom surface 5b. For this reason, on the inner side surfaces after the oxide coating film forming step S180, the locally thick insulating film 130 is formed on the bottom surface 5b and in the lower region on the side wall surface 5a.

According to the method for manufacturing the semiconductor device 1 of the present embodiment, the insulating film 130 having a locally large film thickness can be formed on the inner side surfaces of the trench 5. Accordingly, the insulating performance of the thickly formed part can be further enhanced than the thinly formed part, and therefore the semiconductor device 1 which is small in size and has excellent withstand voltage can be manufactured. In addition, according to the present embodiment, a coating film subjected to film formation using CVD is not used as the insulating film 130, and compared to when an insulating film is formed by CVD, the locally thick insulating film 130 in which incorporation of impurities is curbed can be formed.

In the method for manufacturing the semiconductor device 1 according to the present embodiment, as shown in FIG. 20, the barrier coating film 160 is provided only in the upper region of the side wall coating film 51 in the second film formation step S150 and is not provided in the lower region. For this reason, as shown in FIG. 24, the insulating film 130 which is finally formed has a stepped shape on the side wall surface 5a of the trench 5. Accordingly, the insulating properties at the corner portion in the trench 5 are further enhanced. However, in the second film formation step S150, by providing the barrier coating film 160 on the side wall coating film 51, the insulating film 130 having a uniform film thickness may be formed on the side wall surface 5a.

Each of the constitutions according to the second embodiment will be summarized.

According to the method for manufacturing the semiconductor device 1 of the present embodiment, in the second film formation step S150, the silicon coating film 50 provided on the side wall surface 5a of the trench 5 (that is, the side wall coating film 51) is covered by the barrier coating film 160, and the silicon coating film 50 provided on the bottom surface 5b of the trench 5 (that is, the bottom coating film 52) is exposed from the barrier coating film 160. According to this constitution, the barrier coating film 160 can be formed on the side wall surface 5a of the trench 5, and a locally thick part can be formed on the side wall surface 5a of the trench 5 as a coating film in which the silicon coating film 50 and the barrier coating film 160 are combined.

Similar to the first embodiment (refer to FIG. 2), the method for manufacturing the semiconductor device 1 according to the present embodiment has the trench forming step S30 of forming the trench 5 in the base material 10 before the first film formation step S40. As shown in FIG. 19, the part of the silicon coating film 50, in which the barrier coating film 160 is not formed (or only a thin barrier coating film is formed), is a part subjected to film formation on the bottom surface 5b of the trench 5. Other parts of the silicon coating film 50, in which the barrier coating film 160 is formed, are parts formed on the side wall surface 5a of the trench 5. In this manner, by selecting a region in which the barrier coating film 160 is formed, the film thickness of the insulating film 130 can be made locally large.

In the method for manufacturing the semiconductor device 1 according to the present embodiment, the barrier coating film 160 has a smaller diffusion coefficient of oxygen than silicon oxide. According to this constitution, as shown in FIG. 20, in the first oxidizing step S160, the first oxide coating film 180 can be made thin below the barrier coating film 160, and the first oxide coating film 180 can be formed thick in a part exposed from the barrier coating film 160.

In each of the embodiments and the modification examples thereof described above, a case in which the film thicknesses of the insulating films 30, 30A, and 130 on the bottom surface 5b inside the trench 5 are made locally larger than other parts has been described. However, using a similar technique, an insulating film in the vicinity of the opening of the trench 5 can also be made locally thick. Moreover, even in a structure not having the trench 5, a locally thick insulating film can be formed.

In addition, each of the embodiments and the modification examples thereof described above can be combined together. As an example, a barrier coating film having the material described in the second embodiment (silicon nitride) may be provided at the position of the barrier coating film described in the first embodiment. In addition, similarly, a barrier coating film having the material described in the first embodiment (silicon oxide) may be provided at the position of the barrier coating film described in the second embodiment. In these cases, for example, an insulating film in which the thicknesses of the bottom portion and the side wall portion are reversed can be formed.

According to at least one of the embodiments described above, a coating film having different film thicknesses can be formed on the surface of the base material 10 by the barrier coating films 60, 60A, and 160, and therefore the locally thick insulating films and 30A in which incorporation of impurities is curbed can be formed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for manufacturing a semiconductor device comprising:
a first film formation step of forming a first coating film made of silicon on a surface of a base material made of silicon carbide;
a second film formation step of forming a second coating film on a surface of the first coating film; and
an oxidizing step of thermally oxidizing the first coating film from a surface side to form a third coating film,
wherein in the second film formation step,
on a part of the first coating film, the second coating film is not formed, and the part is exposed, and
alternatively, a film thickness of the second coating film formed on the part of the first coating film is smaller than a film thickness of the second coating film formed on a different part.

2. The method for manufacturing a semiconductor device according to claim 1 further comprising:
an etching step of etching at least a part of the second coating film and the third coating film; and
an oxide coating film forming step of forming a fourth coating film made of silicon oxide on the surface of the base material.

3. The method for manufacturing a semiconductor device according to claim 1 further comprising:
a trench forming step of forming a trench in the base material before the first film formation step,
wherein the part of the first coating film is a part subjected to film formation on a side wall surface of the trench, and
the different part of the first coating film is a part formed on a bottom surface of the trench.

4. The method for manufacturing a semiconductor device according to claim 1 further comprising:
a trench forming step of forming a trench in the base material before the first film formation step,
wherein the part of the first coating film is a part subjected to film formation on a bottom surface of the trench, and
the different part of the first coating film is a part formed on a side wall surface of the trench.

5. The method for manufacturing a semiconductor device according to claim 1,
wherein the second film formation step is a step of forming the second coating film by atomic layer deposition.

6. The method for manufacturing a semiconductor device according to claim 1,
wherein the second coating film is formed of silicon oxide.

7. The method for manufacturing a semiconductor device according to claim 1,
wherein the second coating film has a smaller diffusion coefficient of oxygen than silicon oxide.
